(19) United States
(12) Patent Application Publication
(10) Pub. No.: US 2009/0189212 A1
(43) Pub. Date: Jul. 30, 2009

(54) ELECTRONIC DEVICE HAVING A DOPED REGION WITH A GROUP 13 ATOM

(75) Inventors: Gwyn Robert Jones, Sunnyvale, CA (US); Mark Randolph, San Jose, CA (US)

Correspondence Address: LARSON NEWMAN ABEL & POLANSKY, LLP, 5914 W. COURTYARD DRIVE, SUITE 200, AUSTIN, TX, 78730, US

(73) Assignee: SPANSION LLC, Sunnyvale, CA (US)

(21) Appl. No.: 12/022,795

(22) Filed: Jan. 30, 2008

(51) Int. Cl. H01L 29/792; H01L 21/336

(52) U.S. Cl. 257/324; 438/287; 257/E29.309; 257/E21.423

(57) ABSTRACT

An electronic device includes a memory cell. The memory cell includes a semiconductor region, a first current-carrying electrode adjacent to the semiconductor region, and a first dopant-containing region adjacent to a first current-carrying electrode. The semiconductor region includes a Group 14 atom and the first dopant-containing region includes a Group 13 atom. The Group 13 atom has an atomic number greater than the atomic number of the Group 14 atom.

### CROSS-REFERENCE TO RELATED APPLICATION(S)

### BACKGROUND

1. Field of the Disclosure

The present disclosure relates to processes of forming electronic devices, and more particularly, to processes of forming electronic devices having doped region with a Group 13 element.

2. Description of the Related Art

Electronic devices can include memory cells. In the fabrication of a typical memory cell, a halo implant involves doping regions adjacent to a source/drain (S/D) region with boron. The boron acts to increase the electric field near the S/D region and increase the efficiency of programming the memory cell.

FIG. 1 includes an illustration of a cross-sectional view of a portion of a workpiece 100. The workpiece 100 can include a substrate 102 having electronic components formed within or over substrate 102. The components can include gate structures, including a charge storage stack 106, a gate electrode 116, and spacers 128. The charge storage stack 106 can include a gate dielectric layer 108, a charge storage layer 110, and an insulating layer 112. Within the substrate 102 can be shallow halo regions 118a, 118b and deep halo regions 122a, 122b. The halo regions 118a, 118b, 122a, 122b can be formed by implanting boron into the substrate 102. Additionally, extension regions 126a, 126b and source/drain (S/D) regions 130a, 130b can be formed by implanting n-type dopants, such as phosphorous or arsenic.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a cross-sectional view of a workpiece including a memory cell layer having a boron-containing halo implant. (Prior art)

FIG. 2 includes an illustration of a cross-sectional view of a workpiece after forming a plurality of layers over a substrate.

FIG. 3 includes an illustration of a cross-sectional view of the workpiece of FIG. 4 after patterning a layer to form a gate electrode.

FIGS. 4 and 5 include illustrations of a cross-sectional view of the workpiece of FIG. 3 during forming shallow halo implant regions.

FIG. 6 includes an illustration of a cross-sectional view of the workpiece of FIG. 5 during forming of deep halo implant regions.

FIG. 7 includes an illustration of a cross-sectional view of the workpiece of FIG. 6 after forming extension regions.

FIG. 8 includes an illustration of a cross-sectional view of the workpiece of FIG. 7 after forming spacers.

FIG. 9 includes an illustration of a cross-sectional view of the workpiece of FIG. 8 after forming source/drain regions.

FIG. 10 includes an illustration of a cross-sectional view of a system wherein a processor is coupled to a display and an electronic device formed by a process described herein.

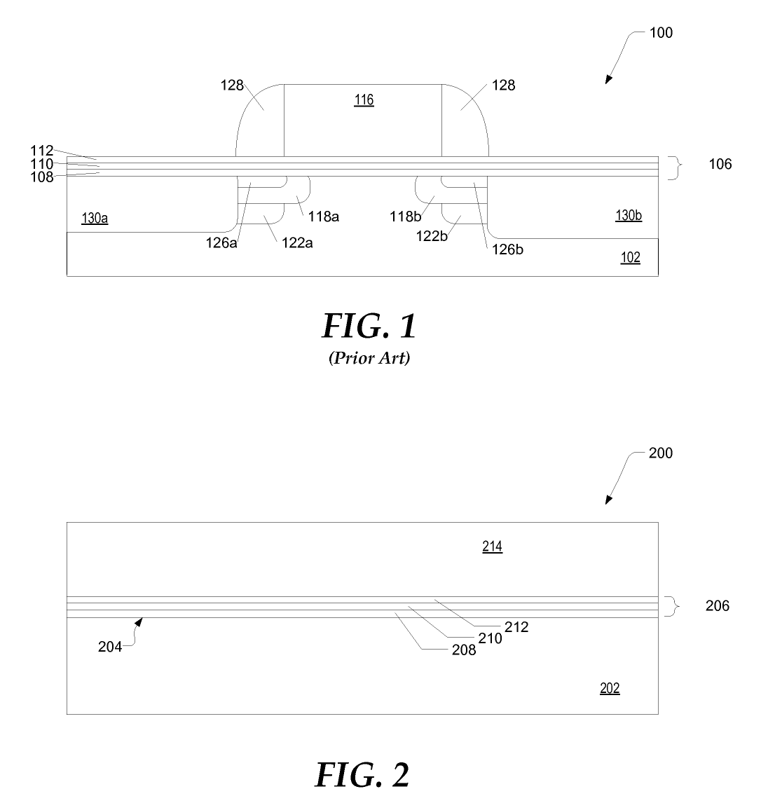

The use of the same reference symbols in different drawings indicates similar or identical items.

### DETAILED DESCRIPTION

In an exemplary embodiment, an electronic device can include a memory cell. The memory cell can include a semiconductor region, a first current-carrying electrode adjacent to the semiconductor region, and a first dopant-containing region adjacent to a first current-carrying electrode. The semiconductor region can include a Group 14 atom and the first dopant-containing region can include a Group 13 atom. The Group 13 atom may have an atomic number greater than the atomic number of the Group 14 atom.

Group numbers corresponding to columns within the Periodic Table of the elements use the “New Notation” convention as seen in the CRC Handbook of Chemistry and Physics, 81^{st} Edition (2000).

Attention is now directed to particular embodiments of forming an electronic device, as illustrated in FIGS. 2 to 7. FIG. 2 includes a cross-sectional view of a portion of a workpiece 200 after forming layers used in memory cells. In the embodiment as illustrated in FIG. 2, the memory cells are nonvolatile memory (NVM) cells.

The workpiece 200 includes a substrate 202 having a primary surface 204. The substrate 200 can include a monocrystalline semiconductor wafer, a semiconductor-on-insulator wafer, a flat panel display (e.g., a silicon layer over a glass electroplate), or other substrate conventionally used to form electronic devices. The substrate may include a Group 14 element, such as silicon, germanium, or any combination thereof. A charge storage stack 206 is formed over the substrate 202. The charge storage stack 206 can include a gate dielectric layer 208, a charge storage layer 210, and an insulating layer 212. In one particular embodiment, the gate dielectric layer 208 may include an oxide layer. Additionally, the insulating layer 212 may include an oxide layer. In an embodiment, the charge storage layer 210 can include a nitride layer, a doped silicon layer, or another layer capable of storing a charge. In the particular embodiment illustrated in FIG. 4, the charge storage layer includes a nitride layer. A conductive layer 214 is formed over the charge storage stack 206. The conductive layer 214 can include doped silicon, a metal, a metal nitride, another suitable gate electrode material, or any combination thereof. The compositions, thickness, and formation techniques used in forming the charge storage stack 206 and the conductive layer 214 can be conventional or proprietary.

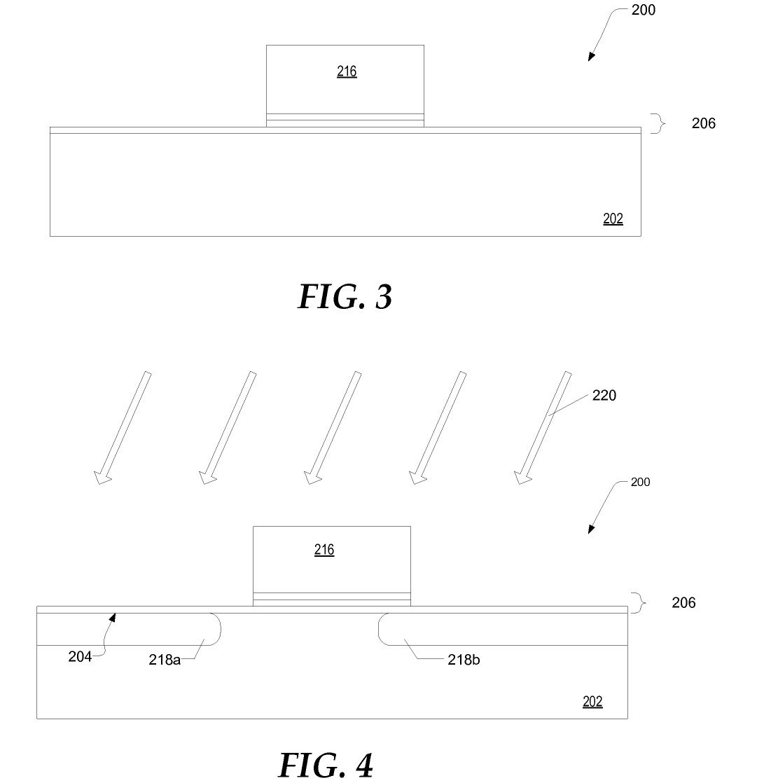

FIG. 3 includes an illustration of a cross-sectional view of the workpiece 200 after forming a gate electrode 216 from the conductive layer 214. The gate electrode 216 can be formed by patterning the conductive layer 214 using a conventional or proprietary technique. Additionally, the insulating layer 212 and the charge storage layer 210 may be patterned to match the gate electrode 216. More or fewer layers of the charge storage stack 206 may be patterned during or after formation of the gate electrode 216.

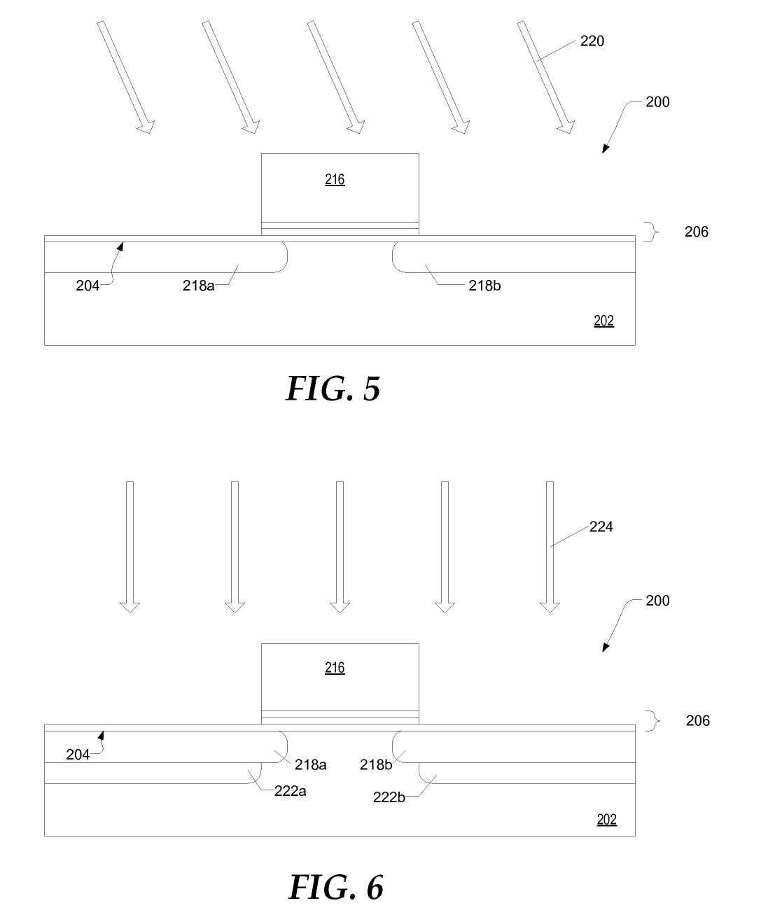

FIGS. 4 and 5 include illustrations of a cross-sectional view of the workpiece 200 during forming of shallow implant regions 218a, 218b. In an embodiment, the shallow implant regions 218a, 218b are implanted with a Group 13 element. Group 13 elements having an atomic number greater than the atomic number of the Group 14 element of the substrate are particularly useful. For example, when the substrate includes silicon or germanium, the implant regions may be implanted with indium, thallium, or any combination thereof. In the particular embodiment illustrated in FIGS. 4 and 5, the shallow implant regions 218a, 218b are implanted with indium. The Group 13 element can be implanted at an angle relative to the primary surface 204. For example, ion implantation 220 can be at an angle at least about 8 degrees from perpendicular to the primary surface. In an embodiment, the angle can be between about 10 degrees and about 25 degrees. Ion implantation 220 may be performed at a dose in a range from about 10¹³ ions/cm² to about 10¹⁵ ions/cm² at an energy of between about 20 keV and about 50 keV. In an exemplary embodiment, the energy can be between about 20 keV and about 30 keV. The projected range may be not greater than about 100 nm. FIG. 5 shows a 180° rotation of the workpiece 200 relative to FIG. 4. Generally, the workpiece 200 may be rotated in 90° increments, such as 90°, 180°, and 270° relative to the initial orientation of the workpiece 200. Alternatively, the ion beam may be rotated while the workpiece 200 remains in place.

FIG. 6 includes an illustration of a cross-sectional view of the workpiece 200 during forming of deep implant regions 222a, 222b. The terms shallow and deep, when used with reference to the implant regions, refers to the relative depth of the peak concentration within the substrate. That is the projected range of the deep implant regions 222a, 222b are at a greater depth from the primary surface 204 than the projected range of the shallow implant regions 218a, 218b. In an embodiment, the deep implant regions 222a, 222b are implanted with a Group 13 element. Group 13 elements having an atomic number greater than the atomic number of the Group 14 element of the substrate are particularly useful. For example, when the substrate includes silicon or germanium, the implant regions may be implanted with indium, thallium, or any combination thereof. In the particular embodiment illustrated in FIG. 6, the shallow implant regions 222a, 222b are implanted with indium. The Group 13 element can be implanted nearly perpendicular to the primary surface 204. To reduce the likelihood of implant channeling, the ion implantation 224 may be provided at an angle relative to perpendicular, such as an angle not greater than about 8 degrees from perpendicular to the primary surface 204. Ion implantation 224 may be performed at a dose of between about 10¹³ ions/cm² and about 10¹⁵ ions/cm² and at an energy of between about 20 keV and about 50 keV. In an exemplary embodiment, the energy may be between about 35 keV and about 50 keV. The projected range can be between about 50 nm and about 200 nm.

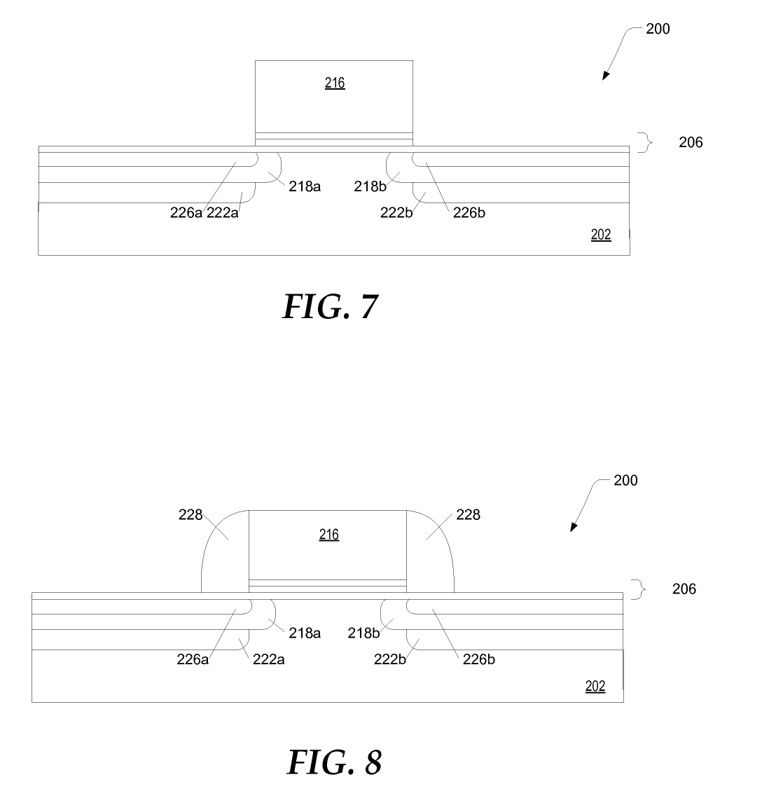

FIG. 7 includes an illustration of a cross-sectional view of the workpiece 200 after formation of extension regions 226a, 226b. In one embodiment, extension regions 226a, 226b are formed in and at the primary surface 204 of the substrate 200. The extension regions 226a, 226b can be lightly doped with an n-type dopant, such as phosphorous. In one embodiment, the extension regions 226a and 226b can be formed by ion implantation with a low-energy ion beam of phosphorous ions. For example, ion implantation may be performed at a dose of between about 10¹¹ ions/cm² and about 10¹⁴ ions/cm² and at an energy of less than about 20 keV.

Forming the shallow implant regions 218a and 218b, the deep halo regions 222a and 222b, and the extension regions 226a and 226b may occur in any order. Additionally, annealing activities may occur between the implantation activities for forming the shallow implant regions 218a and 218b, the deep halo regions 222a and 222b, and the extension regions 226a and 226b.

FIG. 8 includes an illustration of a cross-sectional view of the workpiece 200 after formation of spacers 228. In an embodiment, the spacers 228 are formed by a relatively conformal deposition of an insulator followed by an anisotropic etch. The insulator may be an oxide, a nitride, an oxynitride, or any combination thereof.

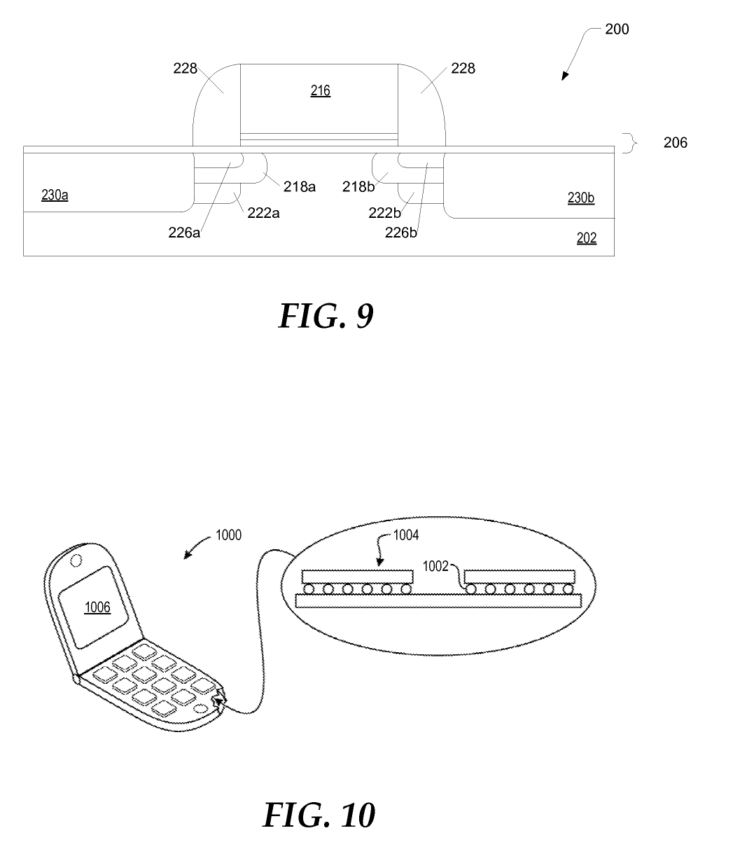

FIG. 9 includes an illustration of a cross-sectional view of the workpiece 200 after formation of the S/D regions 230a, 230b. The gate electrode 216 and the spacers 228 are used as a mask for doping S/D regions 230a, 230b in and at top surface of the substrate 200. In one embodiment, the S/D region 230a can overlap with the shallow halo region 218a and the deep halo region 222a. Similarly, the S/D region 230b can overlap with the shallow halo region 218b and the deep halo region 222b. The S/D regions 230a, 230b can be heavily doped with an n-type dopant, such as arsenic. In one embodiment, the S/D regions 230a, 230b can be formed by ion implantation using a high-dose ion beam of arsenic ions. For example, ion implantation may be performed at a dose at least about 10¹⁵ ions/cm² and at an energy of less than about 40 keV.

In an embodiment, multiple structures (not illustrated) similar to the structure 200 can be formed on a same substrate. Multiple structures may be formed concurrently, sequentially, or any combination thereof.

FIG. 10 includes an illustration of a system 1000. The system 1000 includes the electronic device 1002 formed by the process described herein. In one embodiment, the electronic device 1002 can be an integrated circuit that includes memory cells, such as nonvolatile memory cells, random access memory cells, other suitable memory cells, or any combination thereof. The electronic device 1002 can be part of a standalone memory integrated circuit or may be part of a different type of integrated circuit.

The system 1000 also includes a processor 1004 is coupled to a display 1006 and the electronic device 1002. The processor 1004 can include a central processing unit, a graphical processing unit, another suitable processing unit, or any combination thereof. The processor 1004 may be part of a microcontroller, a microprocessor, a digital signal processor, another suitable data processing integrated circuit or the like. The processor 1004 and the electronic device 1002 can be separate integrated circuits mounted on the same printed wiring board or different printed wiring boards. In another embodiment, the processor 1004 and the electronic device 1002 may reside within the same integrated circuit. In one specific embodiment, the processor 1004 can read data from the electronic device 1002 and render or otherwise provide information to be displayed on the display 1006 of the system 1000.

Embodiments can be used for different types of memory cells. In addition to NVM cells, the process may be used for another type of memory cell, such as a dynamic random access memory (DRAM) cell, a static random access memory (SRAM) cell, a megnetoelectric random access memory (MRAM) cell, or the like.

Embodiments described herein can allow for better control of the dopant profile within the halo regions. For example, a boron atom is relatively small and more readily diffuses within the substrate during thermal treatment of the workpiece, reducing the concentration of the boron and increasing the size of the doped region. As process technologies allow for the reduction in the size of the memory cell, the broadening of the doped region due to diffusion may result in merging of the halo implants on either side of the memory cell. Due to the lower diffusivity of a larger dopant for that same thermal budget, the concentration profile of the dopant, such as Indium, in the halo regions can be more readily controlled. That is, the doped region may undergo less broadening during thermal treatment, better maintaining the concentration profile. Thus, efficiency in programming can be achieved for a smaller cell size through electric field profile considerations while maintaining an acceptable and controllable short channel effects.

Many different aspects and embodiments are possible. Some of those aspects and embodiments are described below. After reading this specification, skilled artisans will appreciate that those aspects and embodiments are only illustrative and do not limit the scope of the present invention.

In a first aspect, an electronic device can include a memory cell. The memory cell can include a semiconductor region, a first current-carrying electrode adjacent to the semiconductor region, and a first dopant-containing region adjacent to a first current-carrying electrode. The semiconductor region can include a Group 14 atom and the first dopant-containing region can include a Group 13 atom. The Group 13 atom can have an atomic number greater than the atomic number of the Group 14 atom. In an embodiment of the first aspect, the Group 13 atom can include indium. In an additional embodiment of the first aspect, the memory cell can be a nonvolatile memory cell.

In another embodiment of the first aspect, the memory cell may also include a second dopant-containing region adjacent to the first current-carrying electrode. The second dopant-containing region can include a Group 13 atom having an atomic number greater than the atomic number of the Group 14 atom.

In a further embodiment of the first aspect, the memory cell may also include a second dopant-containing region within the substrate adjacent to a second current carrying electrode. The second dopant-containing region may include a Group 13 atom having an atomic number greater than the atomic number of the Group 14 atom. In a particular embodiment, the memory cell may also include a third dopant-containing region within the substrate adjacent to the first current carrying electrode; and a fourth dopant-containing region within the substrate adjacent to the second current carrying electrode. The third and fourth dopant-containing regions may include a Group 13 atom having an atomic number greater than the atomic number of the Group 14 atom.

In yet another embodiment of the first aspect, the memory cell may also include a control electrode adjacent to the first current-carrying electrode and the semiconductor region. In a particular embodiment, the memory cell may also include a charge-storage layer disposed between the control electrode and semiconductor region. In a more particular embodiment, the charge storage layer may include silicon nitride.

In a second aspect, a method of forming an electronic device can include doping a semiconductor layer with a Group 13 element and forming a first current-carrying electrode within the semiconductor layer. The first doped region may be adjacent to the first current-carrying electrode with a memory cell. The Group 13 element can have an atomic number greater than the atomic number of a Group 14 element within the semiconductor layer. In an embodiment of the second aspect, the Group 13 element may include indium. In an additional embodiment, the method can also include nitriding an oxide layer before doping the semiconductor layer with the Group 13 element.

In another embodiment of the second aspect, doping can include implanting at a first angle. The first angle may be less than about 8° from perpendicular to the primary surface. In a particular embodiment, doping may include implanting at a second angle. The second angle may be at least about 8° from perpendicular to the primary surface.

In a further embodiment of the second aspect, the method may also include forming a control electrode before doping the semiconductor layer with the Group 13 element. In a particular embodiment, the method may also include forming a charge-storage layer before forming the control electrode. In a more particular embodiment, the charge-storage layer can include silicon nitride.

In a third aspect, an electronic device can include a nonvolatile memory cell. The nonvolatile memory cell can include a substrate, a charge storage stack overlying the substrate, and a control gate electrode overlying the charge storage stack. Within the substrate, the nonvolatile memory cell may also include indium atoms and source/drain regions adjacent to the indium atoms. The indium atoms may have a first peak concentration at a first depth and a second peak concentration at a second depth that is deeper than the first depth.

In one embodiment of the third aspect, the indium atoms may lie within a first doped region that can include the first peak concentration and a second doped region that can include the second peak concentration. The first doped region and the second doped region can be separate doped regions. In another embodiment of the third aspect, the indium atoms may lie within a doped region that can includes a bimodal distribution of indium atoms that can includes the first peak concentration and the second peak concentration.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. An electronic device including a memory cell, wherein the memory cell comprises:
a semiconductor region, wherein the semiconductor region includes a Group 14 atom;
a first current-carrying electrode adjacent to the semiconductor region; and
a first dopant-containing region adjacent to a first current-carrying electrode, wherein the first dopant-containing region includes a Group 13 atom having an atomic number greater than the atomic number of the Group 14 atom.

2. The electronic device of claim 3, wherein the Group 13 atom includes indium.

3. The electronic device of claim 1, wherein the memory cell further comprises a second dopant-containing region adjacent to the first current-carrying electrode, wherein the second dopant-containing region includes a Group 13 atom having an atomic number greater than the atomic number of the Group 14 atom.

4. The electronic device of claim 1, wherein the memory cell further comprises a second dopant-containing region within the substrate adjacent to a second current carrying electrode, wherein the second dopant-containing region includes a Group 13 atom having an atomic number greater than the atomic number of the Group 14 atom.

5. The electronic device of claim 4, wherein the memory cell further comprises:
a third dopant-containing region within the substrate adjacent to the first current carrying electrode; and
a fourth dopant-containing region within the substrate adjacent to the second current carrying electrode,
wherein the third and fourth dopant-containing regions include a Group 13 atom having an atomic number greater than the atomic number of the Group 14 atom.

6. The electronic device of claim 1, wherein the memory cell further comprises a control electrode adjacent to the first current-carrying electrode and the semiconductor region.

7. The electronic device of claim 6, wherein the memory cell further comprises a charge-storage layer, wherein the charge-storage layer is disposed between the control electrode and semiconductor region.

8. The electronic device of claim 7, wherein the charge storage layer includes silicon nitride.

9. The electronic device of claim 1, wherein the memory cell is a nonvolatile memory cell.

10. A method of forming an electronic device comprising:
doping a semiconductor layer with a Group 13 element, wherein the semiconductor layer has a primary surface and includes a Group 14 element, the Group 13 element having an atomic number greater than the atomic number of the Group 14 element;
forming a first current-carrying electrode within the semiconductor layer,
wherein the electronic device includes a memory cell, and within the memory cell, the first doped region is adjacent to the first current-carrying electrode.

11. The method of claim 10, wherein the Group 13 element includes indium.

12. The method of claim 10, wherein doping includes implanting at a first angle, the first angle less than about 8° from perpendicular to the primary surface.

13. The method of claim 12, wherein doping includes implanting at a second angle, the second angle at least about 8° from perpendicular to the primary surface.

14. The method of claim 10, further comprising forming a control electrode before doping the semiconductor layer with the Group 13 element.

15. The method of claim 14, further comprising forming a charge-storage layer before forming the control electrode.

16. The method of claim 15, wherein the charge-storage layer includes silicon nitride.

17. The method of claim 10, further comprising nitriding an oxide layer before doping the semiconductor layer with the Group 13 element.

18. An electronic device including a nonvolatile memory cell, wherein the nonvolatile memory cell comprises:
a substrate;
a charge storage stack overlying the substrate;
a control gate electrode overlying the charge storage stack;
indium atoms within the substrate, wherein the indium atoms have a first peak concentration at a first depth and a second peak concentration at a second depth that is deeper than the first depth; and
source/drain regions within the substrate, wherein within the nonvolatile memory cell, the source/drain regions are adjacent to the indium atoms.

19. The electronic device of claim 18, wherein:
the source/drain regions include a particular source/drain region; and
adjacent to the particular source/drain region, the indium atoms lie within a first doped region that includes the first peak concentration and a second doped region that includes the second peak concentration, wherein the first doped region and the second doped region are separate doped regions.

20. The electronic device of claim 18, wherein:
the source/drain regions include a particular source/drain region; and
adjacent to the particular source/drain region, the indium atoms lie within a doped region that includes a bimodal distribution of indium atoms that includes the first peak concentration and the second peak concentration.
